(19) United States
(12) Patent Application Publication
(10) Pub. No.: US 2011/0189857 A1
(43) Pub. Date: Aug. 4, 2011

(54) CHEMICAL MECHANICAL POLISHING APPARATUS, CHEMICAL MECHANICAL POLISHING METHOD, AND CONTROL PROGRAM

(75) Inventors: Takaaki Matsuoka, Tokyo (JP); Tadahiro Ohmi, Miyagi (JP)

(73) Assignees: TOKYO ELECTRON LIMITED, Tokyo (JP); TOHOKU UNIVERSITY, Sendai-shi (JP)

(21) Appl. No.: 13/120,554

(22) PCT Filed: Aug. 26, 2009
(86) PCT No.: PCT/JP2009/004114

§ 371 Date: Apr. 18, 2011

(30) Foreign Application Priority Data
Sep. 24, 2008 (JP) 2008-244095

(51) Int. Cl. H01L 21/306; C23F 1/08

(52) U.S. Cl. 438/692; 156/345.12; 257/E21.23

(57) ABSTRACT

Scratches and dishing are prevented from being generated when copper, which is deposited on an interlayer insulating film formed of an organic low-k film, is polished during a damascene process. In the CMP apparatus, while a rotating center axis of a rotating head, which has a polishing pad attached thereon, and a rotating center axis of a rotating table, which has a semiconductor wafer disposed face-up thereon, are aligned on the same vertical line, and the rotating head and the rotating table are spin-rotating in the same direction, the rotating head is lowered and the polishing pad touches the semiconductor wafer on the rotating table. Accordingly the polishing pad is prevented from scrubbing in a direction opposite to the rotating direction of the semiconductor wafer in the entire surface of the semiconductor wafer.

### TECHNICAL FIELD

The present invention relates to a chemical mechanical polishing apparatus, chemical mechanical polishing method, and a control program, which are used in a damascene process for forming a copper wire by embedding copper in an interlayer insulating film formed of an organic low-k film.

### BACKGROUND ART

A recent semiconductor integrated circuit, specifically an LSI (Large Scale Integrated Circuit) has a multi-layer wire structure, in which a plurality of wire layers overlap is each other, for minuteness and high integration. In a conventional wire forming process with respect to the multi-layer wire structure, a metal wire pattern is formed by processing a metal film of Al or the like deposited on an insulating film via lithography and dry etching, but the Al wire has low electro-migration resistance, relatively high electric resistance, and wire delay. In this regard, recently, a damascene process of a copper wire is employed in the multi-layer wire forming process.

Meanwhile, capacity between multi-layer wires needs to be reduced for high speed and low power consumption of LSI. Thus, it is essential to employ a low-k film as an interlayer insulating film that is embedded between wires or between wire layers, so as to decrease wire capacity. An inorganic material such as an SiOF film, or a porous film is considered as such a type of low-k film, and an organic material such as a fluorine resin and amorphous fluorocarbon, which has a relative dielectric constant below or equal to 2.5, is also very promising.

Here, referring to FIG. 10, a damascene process of a copper wire using an organic low-k film as an interlayer insulating film will be described.

First, as shown in FIG. 10 (a), etch stop films 102 and 106, which may be formed of SiCN, and organic low-k films 104 and 108, which may be formed of amorphous fluorocarbon, are stacked in an order of 102, 104, 106, and 108 from the bottom on a semiconductor wafer 100 including a lower layer wire (not shown), by using a CVD (Chemical Vapor Deposition) method.

Then, a lithography process and an etching process are repeated so as to form wire grooves 110 in the low-k organic film 108 that is an upper layer and via holes 112 in the low-k organic film 104 that is a lower layer, as shown in FIG. 10 (b). Here, a surface of the semiconductor wafer 100 becomes uneven due to the wire grooves 110 and the via holes 112.

Next, as shown in FIG. 10 (c), a barrier metal 114 is formed on the surface of the semiconductor wafer 100 including the via holes 112 and wire grooves 110, by using a CVD method. The barrier metal 114 may be formed of, for example, TaN. Also, a seed layer (not shown) of copper may be formed on the barrier metal 114, by using a sputtering is method.

Then, as shown in FIG. 10 (d), copper 116 is deposited on the surface of the semiconductor wafer 100 by using an electric field plating method so that the insides of the via holes 112 and wire grooves 110 are filled. Here, an uneven shape due to the wire grooves 110 or the via holes 112 is reflected on a surface of the copper 116.

The copper 116 on the semiconductor wafer 100 is evenly polished via chemical mechanical polishing (CMP) so as to leave the copper 116 only in the via holes 112 and the wire grooves 110 as shown in FIG. 10 (e), thereby forming an embedded copper wire.

The above-described damascene process is a dual damascene process, in which a copper plug and a copper wire are formed at once by simultaneously embedding the via holes 112 and the wire grooves 110 with a film of the copper 116. Meanwhile, a single damascene method separately forms a copper plug and a copper wire by separately embedding the via holes 112 and the wire grooves 110 with the film of the copper 116, but the same CMP process as the dual damascene method is performed in a process of removing unnecessary copper aside from the copper embedded in a hole and a groove.

FIG. 11 shows a conventional representative CMP apparatus. The CMP apparatus pushes a rotating head (upper platen) 124 that fixes and holds the semiconductor wafer 100 against a rotating table (lower platen) 122 having a polishing cloth or a polishing pad 120 attached thereon, and rotates a rotating head 124 and the rotating table 122 while supplying a slurry (abradant) onto the polishing pad 120 from a nozzle 126, thereby polishing and planarizing a lower surface (surface to be processed) of the semiconductor wafer 100 via a chemical action and mechanical polishing.
(Patent Reference 1) Japanese Laid-Open Patent Publication No. 2007-12936

### DISCLOSURE OF THE INVENTION

### Technical Problem

However, when such a conventional CMP apparatus is used to polish copper in a damascene process of a copper wire using an organic low-k film as an interlayer insulating film, a scratch 130 having a groove shape, for example, as shown in FIG. 12, a dishing in is which a center of the copper wire is dented, which is not shown, or the like, is easily generated on the surface of the copper 116 after CMP. When such a scratch or dishing is generated in an embedded wire of damascene, a high frequency current (signal) flowing through the wire surface is largely affected, and thus an LSI may become a defected product.

The present inventor studied a generation mechanism of such a scratch or dishing, and found out that when the semiconductor wafer 100 touches down (touches) the polishing pad 120, a polishing pad 120 scrubs in a direction opposite to the rotating direction of the semiconductor wafer in a part of the surface (surface to be processed) of the semiconductor wafer 100 as shown in FIG. 13, and thus a large shearing stress is applied to the copper 116 of a target object to be polished, specifically protrusions 116a. Accordingly, a small crack is easily generated on the surface of the copper 116 and slurry enters into the small crack, and thus the corresponding spot is excessively polished, thereby causing a scratch or dishing. It is thought that since the copper of the target object to be polished is a relatively soft metal and the low-k organic film forming the interlayer insulating film is weak against an external stress and thus easily gathers a shearing stress, the crack is generated during touch down.

The present invention is invented based on such problems of the conventional technology and consideration of the reasons thereof, and provides a chemical mechanical polishing apparatus, a chemical mechanical polishing method, and a control program, which are capable of forming an embedded copper wire having excellent precision of planarization and stability of electric characteristics by preventing generation of a scratch or dishing when copper, which is deposited on an interlayer insulating film formed of an organic low-k film, is polished in a damascene process.

### Technical Solution

In a method according to a first aspect of the present invention, there is provided a chemical mechanical polishing method for polishing, in a damascene process of a copper wire where the organic film (low-k organic film) having a low dielectric constant is used as is an interlayer insulating film on a semiconductor substrate, a copper deposited on the organic film, the chemical mechanical polishing method including: a first step of, while spin-rotating a semiconductor substrate and a polishing pad in a same direction, making the semiconductor substrate and the polishing pad to touch each other while preventing the polishing pad from scrubbing in a direction opposite to the rotating direction of the semiconductor in a substantially entire region of a target surface of the semiconductor substrate; and a second step of chemically mechanically polishing a copper on the semiconductor substrate by supplying a slurry to a contacting interface between the semiconductor substrate and the polishing pad and controlling a pressure and a relative rotating speed between the semiconductor substrate and the polishing pad.

According to the method of the first aspect, in the first step, since the semiconductor substrate and the polishing pad are rotated in the same direction and the semiconductor substrate and the polishing pad touch each other while preventing the polishing pad from scrubbing in a direction opposite to the rotating direction of the semiconductor substrate in the substantially entire region of the target surface of the semiconductor substrate, a shearing stress applied to copper of a surface layer is low in every spot of the target surface, and a degree of shearing stress gathered in the low-k organic film as the base is small. Accordingly, polishing of copper may be started without generating a crack as the cause of a scratch or dishing in the substantially entire region of the target surface on the substrate.

In a method according to a second aspect of the present invention, there is provided a chemical mechanical polishing method for polishing, in a damascene process of a copper wire where an organic film having a low dielectric constatn is used as an interlayer insulating film on a semiconductor substrate, a copper deposited on the organic film, the chemical mechanical polishing method including: a first step of, while rotating a semiconductor substrate and a polishing pad in a same direction, making the semiconductor substrate and the polishing pad to touch each other while aligning each rotating center axis on a straight line; and a second step of chemically mechanically polishing the copper on the semiconductor substrate by supplying a slurry to a contacting interface between the semiconductor substrate and the polishing pad and controlling a is relative rotating speed and a pressure between the semiconductor substrate and the polishing pad.

According to the method of the second aspect, in the first step, since the semiconductor substrate and the polishing pad are rotated in the same direction and touch each other while aligning the rotating center axes on the straight line, a shearing stress applied to copper on a surface layer is low in every spot of the target surface, and a degree of shearing stress gathered in the low-k organic film as the base is small. Accordingly, polishing of copper may be started without generating a crack as the cause of a scratch or dishing in the substantially entire region of the target surface on the substrate.

Each rotating speed of the semiconductor substrate and the polishing pad in the first step may be suitably set according to a diameter of the substrate, an uneven state of a copper surface, a material of the low-k organic film, a material of the polishing pad, or the like, and may be generally set within a range from 50 rpm to 300 rpm, for example, from 80 rpm to 90 rpm. Alternatively, the rotating speed of them may be different, but the smaller speed difference the more preferable in order to reduce a shock or stress when they touch each other, and it is the most preferable that the speed difference is substantially 0.

Here, it is not preferable to stop the rotation of the semiconductor substrate and the polishing pad in order to set the speed difference to be substantially 0. This is because, when the process proceeds to the second step after the speed difference is set to 0 by stopping the rotation and then the semiconductor substrate and the polishing pad touch each other, a static frictional force higher than a moving frictional force is applied between the semiconductor substrate and the polishing pad, and thus the target surface of the semiconductor substrate may be largely damaged.

In the chemical mechanical polishing method of the present invention, in order not to apply remarkable change of a shearing stress to the copper and the low-k organic film on the semiconductor substrate in the second step, the semiconductor substrate and the polishing pad is preferably rotated in a same direction. Also, it is more preferable that the polishing pad is prevented from scrubbing in a direction opposite to the rotating direction of the semiconductor substrate in the substantially entire region of the target surface of the semiconductor substrate, or the rotating center axis of the semiconductor substrate and is the rotating center axis of the polishing pad is aligned on the straight line.

However, after a protrusion of the copper (film to be processed) is somewhat or considerably polished in an initial stage of the second step, a scratch is hardly generated even when polishing pressure or shearing stress is increased. Accordingly, it is possible to offset the rotating center axis of the semiconductor substrate and the rotating center axis of the polishing pad, and further to vary an offset location of the semiconductor substrate with respect to the polishing pad. Here, polishing efficiency may be increased by using the polishing pad having a sufficiently larger diameter than the semiconductor substrate.

Also, in the second step, a relative rotating speed between the semiconductor substrate and the polishing pad may be suitably set according to the diameter of the substrate, the uneven state of the copper surface, the material of the low-k organic film, the material of the polishing pad, or the like. Very suitably, the relative rotating speed may be controlled by decreasing the rotating speed of the semiconductor substrate to be lower than the rotating speed in the first step while maintaining uniformly the rotating speed of the polishing pad, or the relative rotating speed may be varied. Also, pressure applied to the contacting interface may be gradually increased.

Also, in the second step, the pressure applied to the contacting interface between the semiconductor substrate and the polishing pad may be arbitrarily controlled according to the same conditions above, but generally, a method of gradually increasing the pressure may be employed.

Also, the chemical mechanical polishing method of the present invention may further include a third step of separating the semiconductor substrate and the polishing pad while rotating them in a same direction, in other to end polishing of the copper on the semiconductor substrate, as a very suitable embodiment. As such, it is preferable not to apply remarkably change of the shearing stress to the contacting interface between the semiconductor substrate and the polishing pad, even the last step. Accordingly, it is more preferable that, in the third step, the polishing pad is prevented from scrubbing in a direction opposite to the rotating direction of the semiconductor substrate in the substantially entire region of the target surface of the semiconductor substrate, or the is rotating center axis of the semiconductor substrate and the rotating center axis of the polishing pad are aligned on the straight line. Alternatively, in the third step, a method of offsetting the rotating center axis of the semiconductor substrate and the rotating center axis of the polishing pad may be employed.

In an apparatus according to one aspect of the present invention, there is provided a chemical mechanical polishing apparatus for polishing, in a damascene process of a copper wire where an organic film having a low dielectric constant is used as an interlayer insulating film on a semiconductor substrate, a copper deposited on the organic film, the chemical mechanical polishing apparatus including: a first platen which holds a semiconductor substrate to be detachable and is configured to be rotatable; a first rotating driver which rotates the first platen at a predetermined rotating speed; a second platen which has a polishing pad attached thereon, and is configured to be rotatable; a second rotating driver which rotates the second platen at a predetermined rotating speed; a first actuator which relatively separates or pressurizes and contacts the first platen and the second platen; a control section which controls the first rotating driver, the second rotating driver, and the first actuator to rotate the first platen and the second platen in a same direction and make the semiconductor substrate and the polishing pad to touch each other while preventing the polishing pad from scrubbing in a direction opposite to the rotating direction of the semiconductor substrate in a substantially entire region of a target surface of the semiconductor substrate, and then to chemically mechanically polish copper on the semiconductor substrate; and a slurry supply section which supplies a slurry to a contacting interface between the semiconductor substrate and the polishing pad.

According to the configuration of the above apparatus, the chemical mechanical polishing method of the first aspect of the present invention described above may be very suitably performed.

According to a second aspect of the present invention, there is provided a chemical mechanical polishing apparatus for polishing, in a damascene process of a copper wire where an organic film having a low dielectric constant is used as an interlayer insulating film on a semiconductor substrate, a copper deposited on the organic film, the chemical mechanical polishing apparatus including: a first platen which holds a semiconductor is substrate to be detachable and is configured to be rotatable; a first rotating driver which rotates the first platen at a predetermined rotating speed; a second platen which has a polishing pad attached thereon and is configured to be rotatable; a second rotating driver which rotates the second platen at a predetermined rotating speed; a first actuator which relatively separates or pressurizes and contacts the first platen and the second platen; a control section which controls the first rotating driver, the second rotating driver, and the first actuator to rotate the first platen and the second platen in a same direction and make the first and second platens to touch each other while aligning each rotating center axis on a straight line, and then to chemically mechanically the polish copper on the semiconductor substrate; and a slurry supply section which supplies a slurry to a contacting interface between the semiconductor substrate and the polishing pad.

According to the configuration of the above apparatus, the chemical mechanical polishing method of the second aspect of the present invention described above may be very suitably performed.

The chemical mechanical polishing apparatus of the present invention may further include a second actuator which relatively moves the second platen with respect to the first platen in a direction perpendicular to the rotating center axis, as a very suitable embodiment. Accordingly, in the second and third steps, offset between the rotating center axis of the semiconductor substrate and the rotating center axis of the polishing pad may be very suitably performed.

Also, a control program of the present invention operates in a computer, and controls a chemical mechanical polishing apparatus by the computer so that a chemical mechanical polishing method of the present invention is performed during execution.

### Advantageous Effects

According to a chemical mechanical polishing apparatus, a chemical mechanical polishing method, or a control program of the present invention, generation of a scratch or dishing is prevented via the above configuration and effects when copper deposited on an interlayer insulating film formed of an organic low-k film is polished during a damascene process, thereby forming an embedded copper wire having excellent precision of is planarization and stability of electric characteristics.

### BRIEF DESCRIPTION OF THE DRAWINGS

FIG. 1 is a diagram showing main elements of a CMP apparatus according to one embodiment of the present invention;

FIG. 2 is a flowchart showing main steps of a control program for a CMP process, according to an embodiment;

FIG. 3 is a waveform diagram showing changes in a state change or physical quantity change of each element in terms of time in the CMP process according to an embodiment;

FIG. 4 is a diagram showing a state of a polishing pad touching or contacting a semiconductor wafer in a CMP apparatus according to an embodiment;

FIG. 5 is a plan view showing rotating directions and a relative positional relationship of a semiconductor wafer and a polishing pad in CMP according to an embodiment;

FIG. 6 is a schematic cross-sectional view schematically showing a contacting interface immediately after a polishing pad touches a semiconductor wafer in CMP according to an embodiment;

FIG. 7 is a diagram showing main elements of a CMP apparatus according to an embodiment 2;

FIG. 8 is a plan view showing rotating directions and a relative positional relationship of a semiconductor wafer and a polishing pad according to an embodiment 2;

FIG. 9 is a block diagram showing a configuration example of a main control section in a CMP apparatus according to an embodiment;

FIG. 10 is views showing processes of a damascene process of a copper wire using an organic low-k film as an interlayer insulating film;

FIG. 11 is a view showing a configuration of a conventional representative CMP apparatus;

FIG. 12 is a schematic cross-sectional view showing an example of a defect generated in a conventional CMP apparatus; and

FIG. 13 is a plan view showing rotating directions and a relative positional relationship of a semiconductor wafer and a polishing pad in a conventional CMP apparatus.

### EXPLANATION ON REFERENCE NUMERALS

10: Rotating Head (Upper Platen)
12: Polishing Pad
14: Rotating Table (Lower Platen)
16: Upper Motor
18: Lower Motor
20: Upper Platen Control Section
22: Lower Platen Control Section
24: Main Control Section
28: Lift/Pressurization Actuator
30: Lift/Pressurization Control Section
32: Slurry Supply Section
32: Slurry Supply Pipe
36: Rotary Joint
40: Horizontal Moving Mechanism
100: Semiconductor Wafer
104, 108: Low-k Film (Interlayer Insulating Film)
106: Copper

### BEST MODE FOR CARRYING OUT THE INVENTION

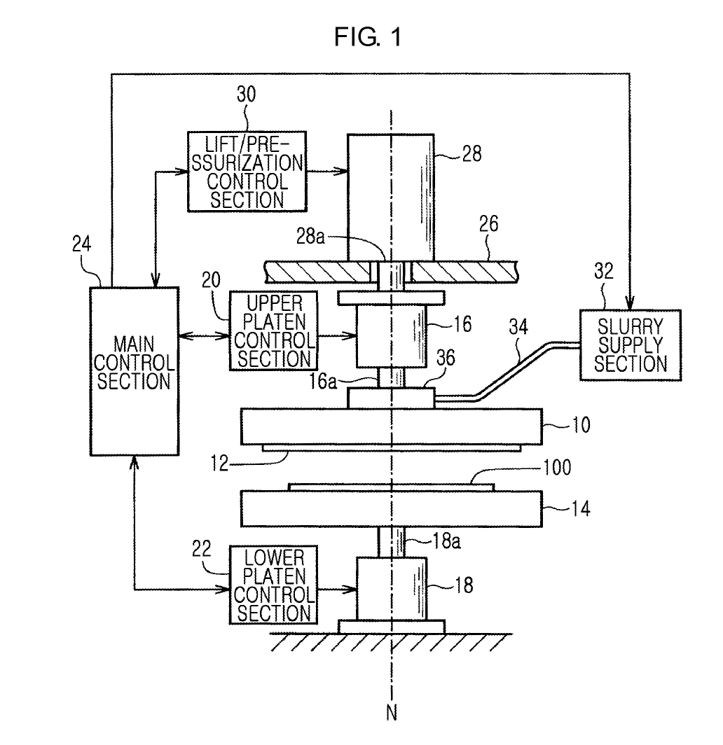

Hereinafter, very suitable embodiments of the present invention will be described with reference to FIGS. 1 through 9.

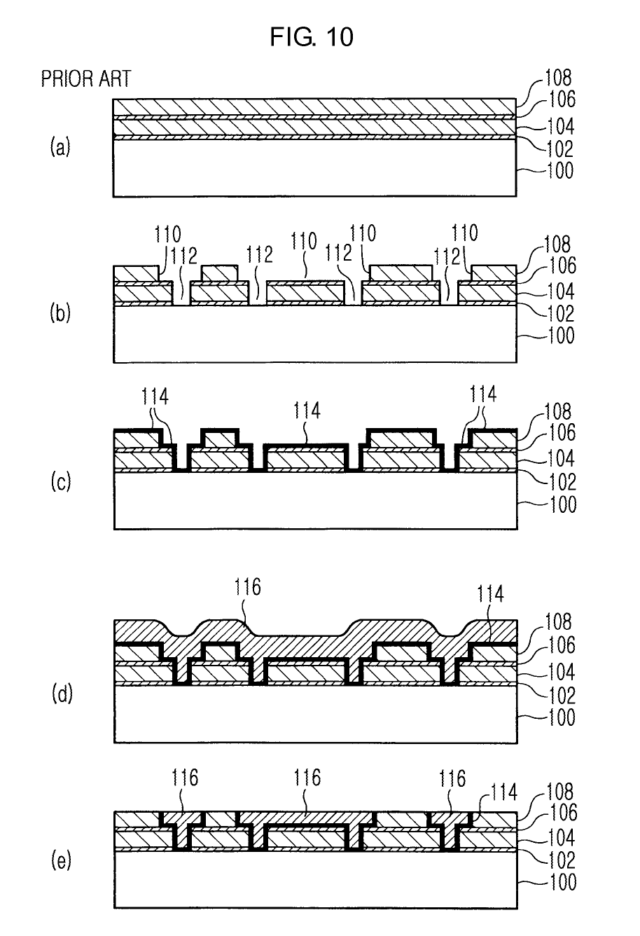

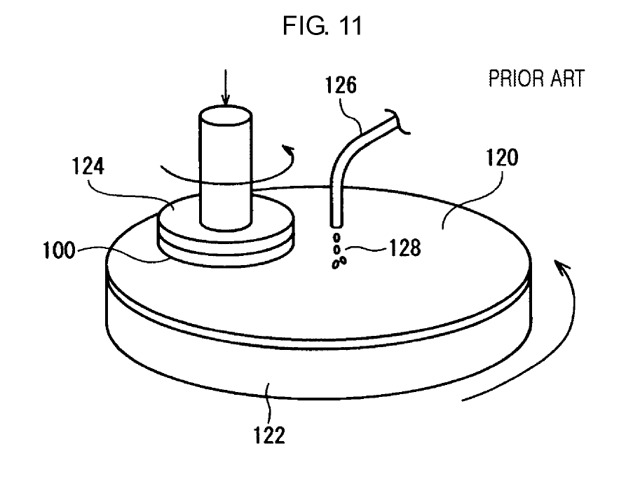

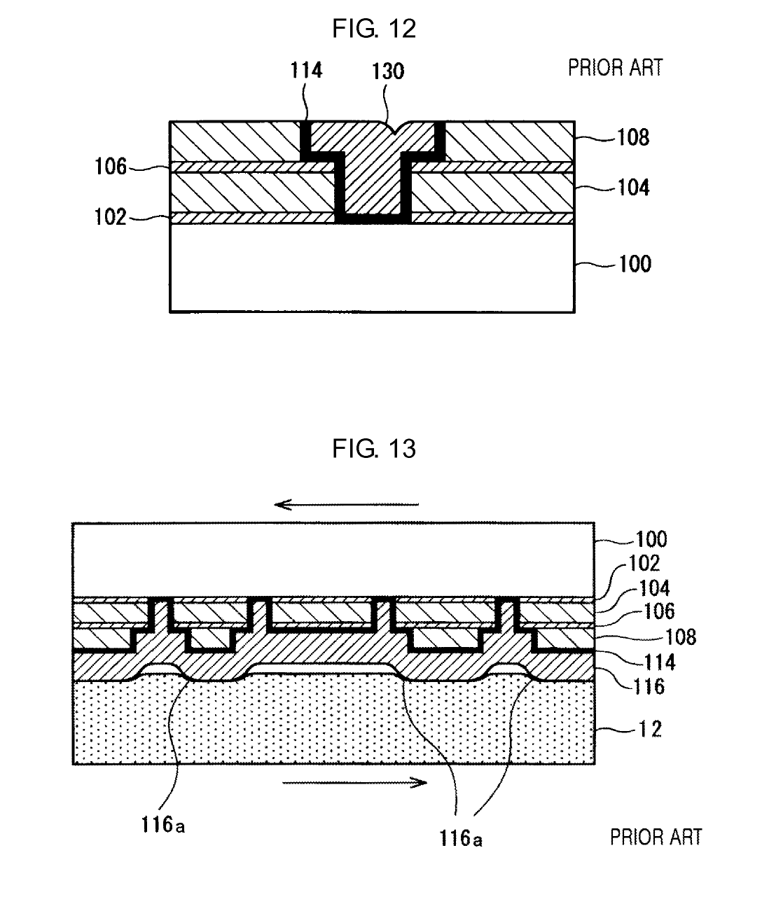

FIG. 1 is a diagram showing main elements of a CMP (chemical mechanical polishing) apparatus according to an embodiment of the present invention. The CMP apparatus may be used very suitably in a damascene process for forming an embedded copper wire, and for example, may be used in the CMP process ((d) to (e) of FIG. 10) for is planarly polishing the copper 116 deposited on the low-k organic film (interlayer insulating film) 108 of the semiconductor wafer 100 in the damascene process of FIG. 10.

In the CMP apparatus, a polishing pad 12 is attached to a rotating head (upper platen) 10 that is spin-rotatable and liftable, and a semiconductor wafer 100 is disposed face-up on a rotating table (lower platen) 14 that is spin-rotatable and stationary. The rotating table 14 includes a holding means, for example, a vacuum chuck (not shown), for holding the semiconductor wafer 100 to be freely detachable. The rotating head 10 is connected to a rotating axis 16a of an upper motor 16, and the rotating table 14 is connected to a rotating axis 18a of a lower motor 18. As shown, a rotating center axis of the rotating head 10, i.e., the rotating axis 16a of the upper motor 16, and a rotating center axis of the rotating table 14, i.e., the rotating axis 18a of the lower motor 18, are on the same vertical line N, and thus the rotating head 10 and the rotating table 14 are directly facing each other.

An upper platen control section 20 and a lower platen control section 22 have a motor driving circuit for supplying a driving current respectively to the upper motor 16 and the lower motor 18, and respectively control rotating operations (rotation start/stop, rotating speed, etc.) of the rotating head 10 and the rotating table 14 according to a control signal from a main control section 24.

The rotating head 10 and the upper motor 16 are connected to a driving axis 28a of a lift/pressurization actuator 28 that is fixed to a holder or frame 26. The lift/pressurization actuator 28 is formed of, for example, an air cylinder or motor built-in linear actuator, and the driving axis 28a is aligned with the vertical line N. A lift/pressurization control section 30 includes a pneumatic circuit or a driving circuit for supplying compressed air or a driving current to the actuator 28, and controls lift and press power of the rotating head 10 according to instructions of the main control section 24.

A slurry supply section 32 includes, for example, a tank storing a slurry (abradant) formed of a polishing liquid including grains of alumina, and a pump discharging the slurry from the tank. An outlet side of the pump is connected to one end of a slurry supply pipe 34. Other end of the slurry supply pipe 34 is connected to a slurry introducing section (not shown) inside the rotating head 10 through a rotary joint 36 connected to the rotating is axis 16a of the upper motor 16. A slurry passage (not shown) passing from the slurry introducing section to the polishing pad is also provided in the rotating head 10. The slurry discharged from the slurry supply section 32 is transmitted to the polishing pad 12 through the slurry supply pipe 34, the rotary joint 36, and the slurry introducing section and the slurry passage in the rotating head 10, and oozes from an entire surface of the polishing pad 12.

The main control section 24 includes a microcomputer, and controls operations of each element in the apparatus, specifically the rotating head 10, the rotating table 14, the lift/pressurization actuator 28, and the slurry supply section 32, and operations (sequence) of the entire apparatus, according to software (program) stored in an external memory or an internal memory.

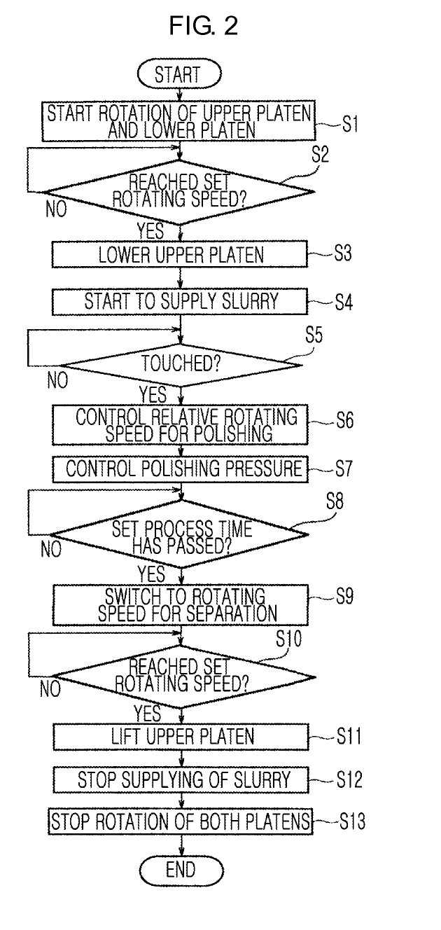

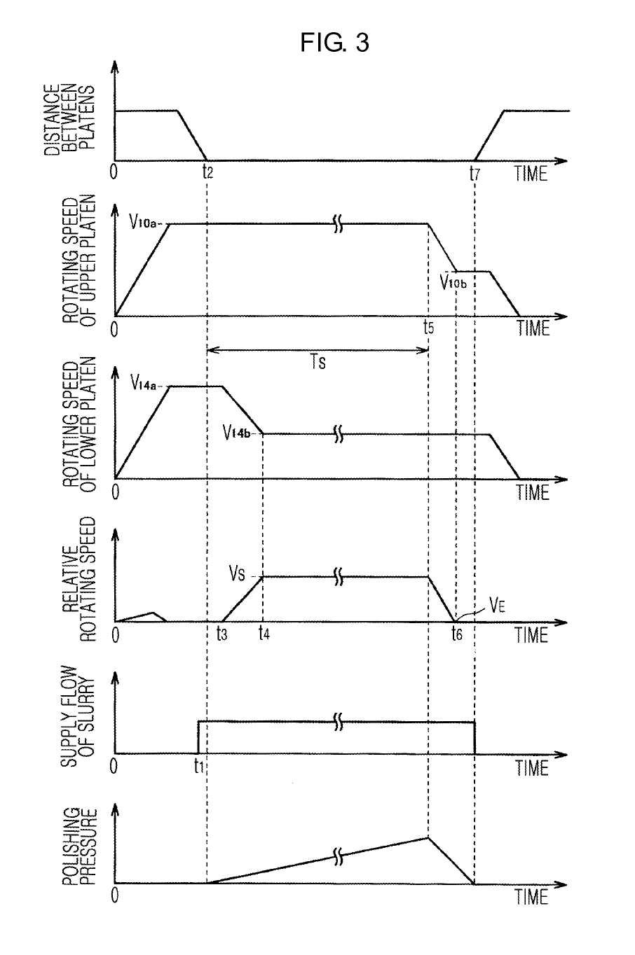

Next, an operation of the CMP apparatus according to the present embodiment will be described with respect to FIGS. 2 through 6. FIG. 2 shows main steps of a control program executed in the main control section 24 for the CMP process during the damascene process for forming an embedded copper wire. FIG. 3 shows a state change of or physical quantity change of each element in terms of time in the CMP process.

In an initial state, as shown in FIG. 1, the rotating head 10 is disposed at an original location set above the rotating table 14, and the polishing pad 12 is separated from the semiconductor wafer 100 on the rotating table 14.

The main control section 24 first activates each of the upper motor 16 and the lower motor 18 through the upper platen control section 20 and the lower platen control section 22 so as to increase each of rotating speeds of the rotating head (upper platen) 10 and the rotating table (lower platen) 14 to speeds V₁₀ₐ and V₁₄ₐ for touch down (touch) (Steps S₁ and S₂).

Here, the rotating speeds V₁₀ₐ and V₁₄ₐ for touch down of the rotating head 10 and the rotating table 14 may be set to a suitable value according to a diameter of the semiconductor wafer 100, an uneven state of a surface of the semiconductor wafer 100, a material of the polishing pad 12, or the like, but may be generally set in the range from 50 rpm to 300 rpm, for example, from 80 rpm to 90 rpm. Also, it does not matter even if V₁₀ₐ>V₁₄ₐ or V₁₀ₐ<V₁₄ₐ, but it is preferable that V₁₀ₐ=V₁₄ₐ.

The upper platen control section 20 and the lower platen control section 22 are capable of controlling the rotating speeds of the polishing pad 12 and the rotating table 14 in a feedback method by using a rotating speed detector, for example, a rotary encoder (not shown) or the like, and are capable of notifying to the main control section 24 about the states at a point of time when the rotating speeds respectively reach or are stabilized at the set points V₁₀ₐ and V₁₄ₐ, by using a status signal, or the like.

Next, the main control section 24 lowers the rotating head 10 by using the lift/pressurization actuator 28 through the lift/pressurization control section 30 (Step S₃), and instructs the slurry supply section 32 to start the discharge of the slurry at a predetermined timing based on a lowering distance or a height location of the rotating head 10, preferably immediately before the polishing pad 12 touches down the semiconductor wafer 100 on the rotating table 14 (time t₁) (Step S₄). As described above, the slurry discharged from the slurry supply section 32 is transmitted to the polishing pad 12 through the slurry supply pipe 34, the rotary joint 36, and the slurry introducing section and the slurry passage in the rotating head 10, and oozes from the entire surface of the polishing pad 12.

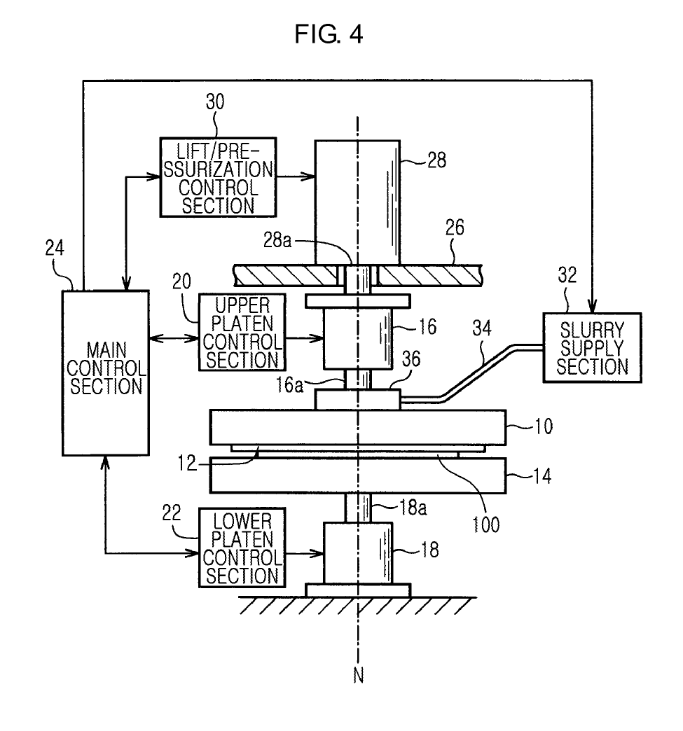

Then, the main control section 24 checks the touch down of the polishing pad 12 and the semiconductor wafer 100 (Step S₅, time t₂). The checking of the touch down may be based on, for example, the lowering distance or the height location of the rotating head 10. However, it is preferable that a method of detecting a change of a rotating torque of the upper motor 16 is employed. FIG. 4 shows a state of the polishing pad 12 touching or contacting the semiconductor wafer 100.

After the touch down is checked, the main control section 24 controls a relative rotating speed between the rotating head 10 and the rotating table 14 to a predetermined value suitable to polish (Step S₆). For example, as shown in FIG. 3, the rotating speed of the rotating table 14 is linearly decreased to a set point V_{14b} lower than the set point V₁₄ₐ for touch down while maintaining the rotating speed of the rotating head 10 at the set point V₁₀ₐ for touch down, thereby linearly increasing the relative rotating speed to a set point V_{S} for polishing (time t₃ to time t₄). The set point Vₛ of the relative rotating speed for polishing may be selected to be a suitable value, for example from 3 to 30 rpm, according is to the diameter of the semiconductor wafer 100, the uneven state of the surface, the material of the polishing pad 12, or the like, or may be varied during polishing.

Meanwhile, the main control section 24 controls press power, i.e., polishing pressure, of the polishing pad 12 against the semiconductor wafer 100 (Step S₇) by using the lift/pressurization actuator 28 through the lift/pressurization control section 30, and generally gradually (for example, linearly) increases the press power as a process time passes.

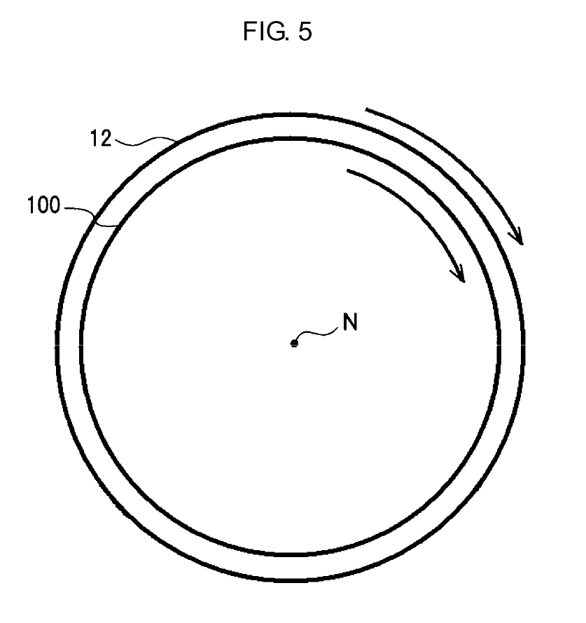

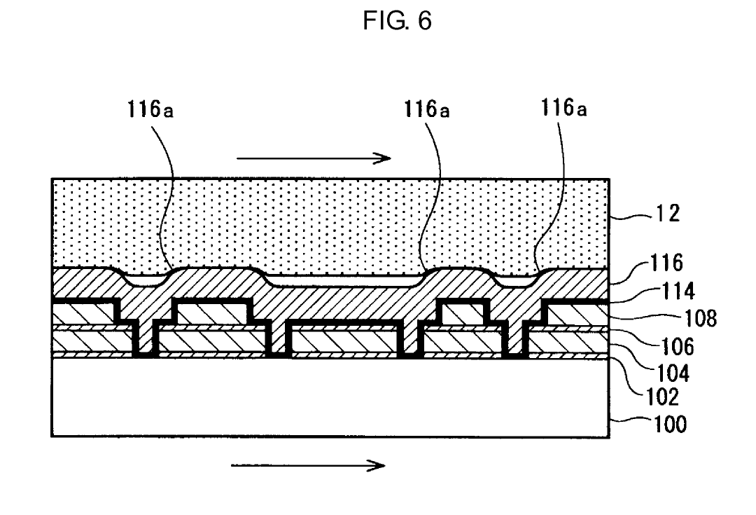

In the present embodiment, the semiconductor wafer 100 and the polishing pad 12 align their rotating centers on the same straight line N and are spin-rotated in the same direction as shown in FIG. 5, during the touch down. Accordingly, in a contacting interface between the semiconductor wafer 100 and the polishing pad 12, since the polishing pad 12 does not scrub in a direction opposite to the rotating direction of the semiconductor wafer on the entire region of the surface of the semiconductor wafer 100 even when the polishing pad 12 presses and contacts the surface of the semiconductor wafer 100 as shown in FIG. 6, a shearing stress applied to the copper 116, specifically the protrusion 116a, is small in every spot of a target surface, and a degree of the shearing stress gathering in the low-k organic films 108 and 104 as the base is also small. Thus, the polishing of the copper 116 may be started without generating a crack as cause of scratch or a dishing in the entire region of the surface of the semiconductor wafer 100.

Also, in the present embodiment, since the relative rotating speed and the polishing pressure are gradually varied or adjusted while spin-rotating the semiconductor wafer 100 and the polishing pad 12 in the same direction after aligning the rotating centers on the same straight line N as shown in FIG. 5 even after the touch down, the shearing stress is not remarkably changed in any part of the surface of the semiconductor wafer 100, and the polishing of the copper 116 may be stably performed.

When a predetermined polishing process time (set time) T_{S} is passed from the time of touch down (time t₂) (Step S₈, time t₅), the main control section 24 switches the relative rotating speed between the rotating head 10 and the rotating table 14 to a rotating speed V_{E} for separation (Steps S₉ and S₁₀) through the upper platen control section 20 and the lower platen control section 22, in order to end the polishing. The rotating speed V_{E} for is separation may be preferably as small as possible, and may be most preferably set to 0 (V_{E}=0). In this example, the relative rotating speed is adjusted to the set point V_{E}(0) by decreasing the rotating speed of the rotating head 10 from the rotating speed V₁₀, at that time to the set point V_{10b}(V_{10b}=V_{14b}) for separation (time t₅ to time t₆).

Also, in order to obtain the timing of ending the polishing, it may use a method that detects the change of rotating torque when the polishing pad 12 polishes the barrier metal 114 on the low-k organic film 108 by the upper platen control section 20 or the lower platen control section 22.

Next, the main control section 24 separates the semiconductor wafer 100 and the polishing pad 12 by lifting the rotating head 10 by using the lift/pressurization actuator 28 through the lift/pressurization control section 30 (Step S₁₁, time t₇). Also, at the nearly same time, the main control section 24 instructs the slurry supply section 32 to stop the supply of the slurry (Step S₁₂). Then, the rotations of the rotating head 10 and the rotating table 14 are stopped (Step S₁₃) by using the upper platen control section 20 and the lower platen control section 22.

As described above, in the present embodiment, since the semiconductor wafer 100 and the polishing pad 12 are spin-rotated in the same direction while aligning the rotating centers on the same straight line N as shown in FIG. 5, even in the step of ending the polishing, and are further smoothly separated from each other by reducing the relative rotating speed (preferably to 0), a possibility of crack generation on the surface of the semiconductor wafer 100 (the surface of the copper 116 and the surface of the low-k organic film 108) may be reduced as much as possible.

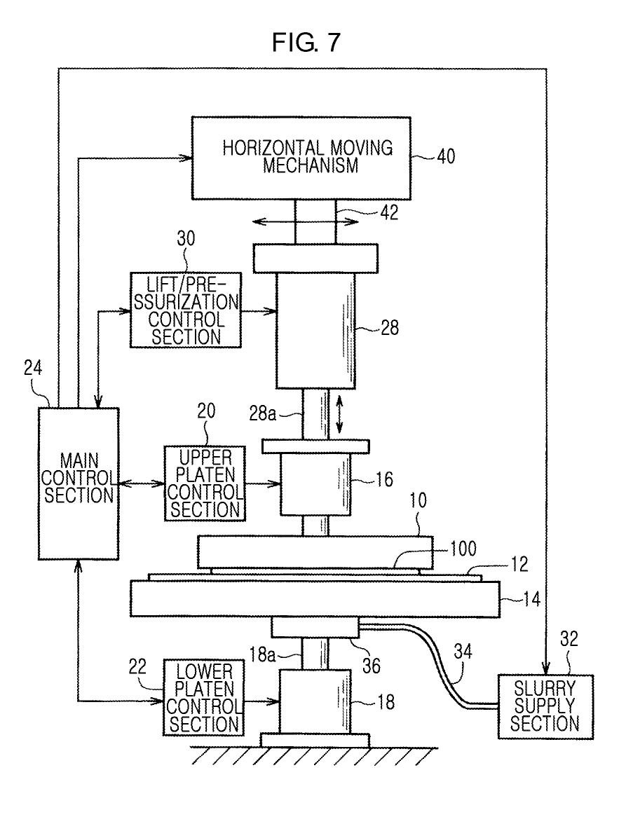

FIG. 7 is a diagram showing a main configuration of a CMP apparatus according to an embodiment 2. The same reference numerals are denoted to the elements having the same configuration or functions as the CMP apparatus (FIG. 1) of the embodiment 1.

In the present embodiment, the semiconductor wafer 100 is disposed face-down on the rotating head (upper platen) 10, and the polishing pad 12 is attached to the rotating table (lower platen) 14 having a remarkably large diameter, for example, twice the rotating head 10. Also it is possible to align the rotating center axis of the rotating head 10 and the rotating center axis of the rotating table 14 on the same axis, or arbitrarily offset the is rotating center axes of the rotating head 10 and the rotating table 14.

In detail, the lift/pressurization actuator 28 connected to the rotating head 10 through the upper motor 16 is moveable in one horizontal direction (X direction), and the location of the lift/pressurization actuator 28, further the location of the rotating head 10 is variable in a horizontal direction by a horizontal moving mechanism 40 provided above a part of the lift/pressurization actuator 28.

Also, the rotating head 10 includes a holding means, for example, a vacuum chuck (not shown), for holding the semiconductor wafer 100 to be freely detached. The slurry supply pipe 34 is connected to a slurry introducing section (not shown) in the rotating table 14 through the rotary joint 36 connected to the rotating axis 18a of the lower motor 18. A slurry passage (not shown) passing from the slurry introducing section to the polishing pad is provided in the rotating table 14. The slurry discharged from the slurry supply section 32 is transmitted to the polishing pad 12 through the slurry supply pipe 34, the rotary joint 36, and the slurry introduction section and the slurry passage in the rotating table 14, and oozes from the entire surface of the polishing pad 12.

In the present embodiment, when a CMP process is started, the rotating head 10 and the rotating table 14 may be touched down with each other while rotating in the same direction and aligning each of the rotating center axes, in the same manner as the embodiment 1. Accordingly, in the contacting interface of the semiconductor wafer 100 and the polishing pad 12, since the polishing pad 12 does not scrub in a direction opposite to the rotating direction of semiconductor wafer 100 in any part of the surface of the semiconductor wafer 100 even when the polishing pad 12 presses and contacts the surface (target surface) of the semiconductor wafer 100 as shown in FIG. 6, the shearing stress applied to the copper 116 (specifically the protrusion 116a) on a surface layer is small, and a degree of the shearing stress gathered in the low-k organic films 108 and 104 as the base is small. Thus, the polishing of the copper 116 may be started without generating a crack as cause of a scratch or dishing on the entire surface of the semiconductor wafer 100.

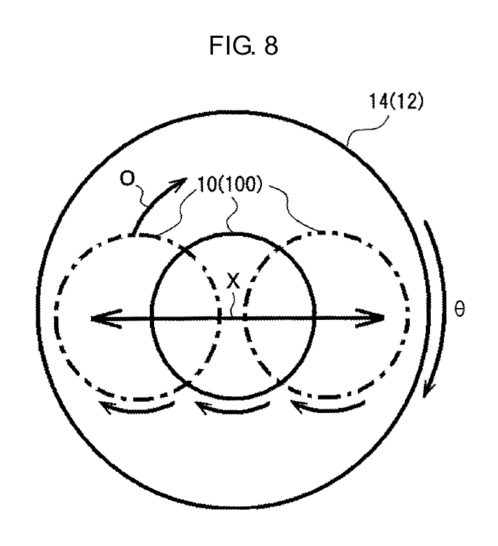

Also, after a predetermined time is passed from the time of the touch down while the relative rotating speed between the rotating head 10 and the rotating table 14 is is adjusted to the set point Vₛ preferably after the protrusion 116a of the copper 116 on the semiconductor wafer 100 is considerably polished, the horizontal moving mechanism 40 is activated. Then, by means of the horizontal moving mechanism 40, the rotating center axis of the semiconductor wafer 100 is misaligned from the rotating center axis of the polishing pad 12 as shown in FIG. 8, and the polishing process is performed at the offset location.

Here, as shown in FIG. 8, the offset location of the rotating head 10 (the semiconductor wafer 100) with respect to the rotating table 14 (the polishing pad 12) may move in a straight line in a direction indicated by an arrow X, or may move in an annular pattern in a direction indicated by an arrow θ. In such an offset relationship, the surface (target surface) of the semiconductor wafer 100 includes a part where the polishing pad 12 scrubs in a direction opposite to the rotating direction of the semiconductor and a part where the polishing pad 12 scrub in same direction as the rotating direction of the semiconductor. However, there is caused no crack on the surface as the protrusion 116a (FIG. 6) of the copper 116 of the film to be processed is considerably polished, and thus a concern about scratch or dishing generation is low even when a relatively large shearing stress is applied thereto.

Meanwhile, in the offset method, a supply speed of the slurry or a polishing speed may be increased since a large area of the polishing pad 12 having a large diameter is efficiently used to polish the semiconductor wafer 100.

When the polishing is ended, it is possible to separate the semiconductor wafer 100 from the polishing pad 12 at the offset location, but it is preferable to separate the semiconductor wafer 100 from the polishing pad 12 by returning the center of the rotating head 10 to the center of the rotating table 14 and decreasing the relative rotating speed (preferably to 0). Accordingly, a possibility of crack generation on the surface of the semiconductor wafer 100 (the surface of the copper 116 and the surface of the low-k organic film 108) may be reduced as much as possible when the polishing is ended.

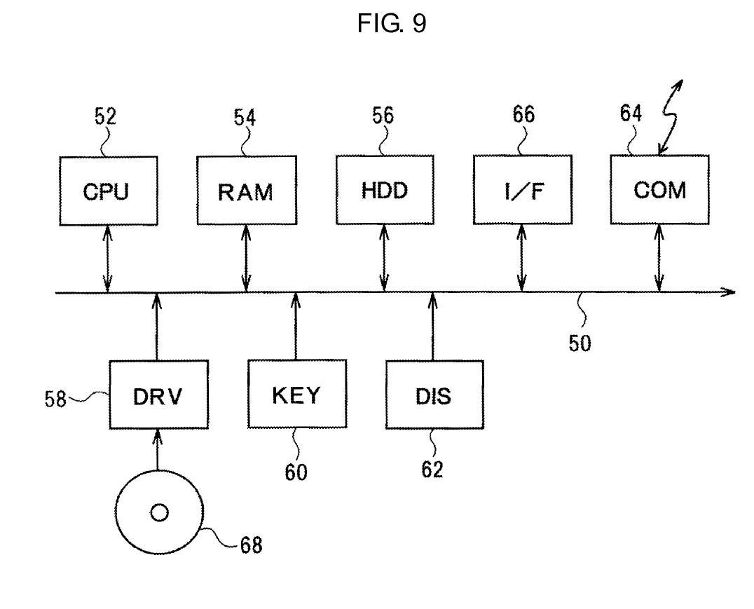

FIG. 9 shows a configuration example of the main control section 24 for controlling each element and entire sequence of the CMP apparatus (FIG. 1 and FIG. 7) in order to perform the CMP process method according to the above embodiment.

The main control section 24 of the configuration example includes a processor (CPU) 52, an internal memory (RAM) 54, a program storage device (HDD) 56, an external memory drive (DRV) 58 such as a flash memory and an optical disk, an input device (KEY) 60 such as a keyboard and a mouse, a display device (DIS) 62, a network and interface (COM) 64, and a peripheral interface (I/F) 66, which are connected through a bus 50.

The processor CPU 52 reads out a code of a required program from a storage medium 68 such as a flash memory and an optical disk in the external memory drive (DRV) 58, and stores the code in the HDD 56. Alternatively, the required program may be downloaded from a network through the network and interface 64. Also, the processor (CPU) 52 loads a code of a program required in each step or each scene from the HDD 56 onto the working memory (RAM) 54 so as to execute each step, and performs a required operation process to control each element in the apparatus through the peripheral interface 66. Programs for executing the CMP method described in the above embodiments are all executed in this computer system.

1. A chemical mechanical polishing method for polishing, in a damascene process of a copper wire where an organic film having a low dielectric constant is used as an interlayer insulating film on a semiconductor substrate, a copper deposited on the organic film,
the chemical mechanical polishing method comprising:
a first step of, while rotating a semiconductor substrate and a polishing pad in a same direction, making the semiconductor substrate and the polishing pad to touch each other while preventing the polishing pad from scrubbing in a direction opposite to the rotating direction of the semiconductor substrate in a substantially entire region of a target surface of the semiconductor substrate; and
a second step of chemically mechanically polishing the copper on the semiconductor substrate by supplying a slurry to a contacting interface between the semiconductor substrate and the polishing pad and controlling a pressure and a relative rotating speed between the semiconductor substrate and the polishing pad.

2. A chemical mechanical polishing method for polishing, in a damascene process of a copper wire where an organic film having a low dielectric constant is used as an interlayer insulating film on a semiconductor substrate, a copper deposited on the organic film,
the chemical mechanical polishing method comprising:
a first step of, while rotating a semiconductor substrate and a polishing pad in a same direction, making the semiconductor substrate and the polishing pad to touch each other while aligning each rotating center axis on a straight line; and
a second step of chemically mechanically polishing the copper on the semiconductor substrate by supplying a slurry to a contacting interface between the semiconductor substrate and the polishing pad and controlling a relative rotating speed and a pressure between the semiconductor substrate and the polishing pad.

3. The chemical mechanical polishing method of claim 1, wherein, in the first step, each rotating speed of the semiconductor substrate and the polishing pad is set within a range from 50 rpm to 300 rpm.

4. The chemical mechanical polishing method of claim 3, wherein, in the first step, each rotating speed of the semiconductor substrate and the polishing pad is set within a range from 80 rpm to 90 rpm.

5. The chemical mechanical polishing method of claim 1, wherein, in the first step, a difference between a rotating speed of the semiconductor substrate and a rotating speed of the polishing pad is substantially 0.

6. The chemical mechanical polishing method of claim 1, wherein, in the second step, the semiconductor substrate and the polishing pad are rotated in a same direction.

7. The chemical mechanical polishing method of claim 6, wherein, in the second step, the polishing pad is prevented from scrubbing in a direction opposite to the rotating direction of the semiconductor substrate in a substantially entire region of the target surface of the semiconductor substrate.

8. The chemical mechanical polishing method of claim of claim 6, wherein, in the second step, the rotating center axis of the semiconductor substrate and the rotating center axis of the polishing pad are aligned on the straight line.

9. The chemical mechanical polishing method of claim 6, wherein, in the second step, the rotating center axis of the semiconductor substrate and the rotating center axis of the polishing pad are offset.

10. The chemical mechanical polishing method of claim 9, wherein, in the second step, an offset location of the semiconductor substrate with respect to the polishing pad is varied.

11. The chemical mechanical polishing method of claim 1, wherein, in the second step, the rotating speed of the polishing pad is uniformly maintained and the rotating speed of the semiconductor substrate is lower than the rotating speed in the first process.

12. The chemical mechanical polishing method of claim 1, wherein, in the second step, the relative rotating speed of the semiconductor substrate and the polishing pad is varied.

13. The chemical mechanical polishing method of claim 1, wherein, in the second step, pressure applied to the contacting interface is gradually increased.

14. The chemical mechanical polishing method of claim 1, further comprising:
a third step of separating the semiconductor substrate and the polishing pad while rotating them in a same direction so as to end the polishing of copper on the semiconductor substrate.

15. The chemical mechanical polishing method of claim 14, wherein, in the third step, the polishing pad is prevented from scrubbing in a direction opposite to the rotating direction of the semiconductor substrate in a substantially entire region of the target surface of the semiconductor substrate.

16. The chemical mechanical polishing method of claim 14, wherein, in the third step, the rotating center axis of the semiconductor substrate and the rotating center axis of the polishing pad are aligned on the straight line.

17. The chemical mechanical polishing method of claim 14, wherein, in the third step, the rotating center axis of the semiconductor substrate and the rotating center axis of the polishing pad are offset.

18. The chemical mechanical polishing method of claim 14, wherein, in the third step, a difference between a rotating speed of the semiconductor substrate and a rotating speed of the polishing pad is substantially 0.

19. A computer executable program recorded in a recording medium for a computer to control a chemical mechanical polishing apparatus so that the chemical mechanical polishing method of claim 1 is performed during execution.

20. A chemical mechanical polishing apparatus for polishing, in a damascene process of a copper wire where an organic film having a low dielectric constant is used as an interlayer insulating film on a semiconductor substrate, a copper deposited on the organic film,
the chemical mechanical polishing apparatus comprising:
a first platen which holds a semiconductor substrate to be detachable and is configured to be rotatable;
a first rotating driver which rotates the first platen at a predetermined rotating speed;
a second platen which has a polishing pad attached thereon and is configured to be rotatable;
a second rotating driver which rotates the second platen at a predetermined rotating speed;
a first actuator which relatively separates or pressurizes and contacts the first platen and the second platen;
a control section which controls the first rotating driver, the second rotating driver, and the first actuator to rotate the first platen and the second platen in a same direction and make the semiconductor substrate and the polishing pad to touch each other while preventing the polishing pad from scrubbing in a direction opposite to the rotating direction of the semiconductor substrate in a substantially entire region of a target surface of the semiconductor substrate and then to chemically mechanically polish copper on the semiconductor substrate; and
a slurry supply section which supplies a slurry to a contacting interface between the semiconductor substrate and the polishing pad.

21. A chemical mechanical polishing apparatus for polishing, in a damascene process of a copper wire where an organic film having a low dielectric constant is used as an interlayer insulating film on a semiconductor substrate, a copper deposited on the organic film,
the chemical mechanical polishing apparatus comprising:
a first platen which holds a semiconductor substrate to be detachable and is configured to be rotatable;
a first rotating driver which rotates the first platen at a predetermined rotating speed;
a second platen which has a polishing pad attached thereon and is configured to be rotatable;
a second rotating driver which rotates the second platen at a predetermined rotating speed;
a first actuator which relatively separates or pressurizes and contacts the first platen and the second platen;
a control section which controls the first rotating driver, the second rotating driver, and the first actuator to rotate the first platen and the second platen in a same direction and make the first and second platens to touch each other while aligning each rotating center axis on a straight line, and then to chemically mechanically polish the copper on the semiconductor substrate; and
a slurry supply section which supplies a slurry to a contacting interface between the semiconductor substrate and the polishing pad.

22. The chemical mechanical polishing apparatus of claim 1, further comprising:
a second actuator which relatively moves the second platen with respect to the first platen in a direction perpendicular to the rotating center axis.
